(19) United States
(12) Patent Application Publication
(10) Pub. No.: US 2001/0050598 A1
(43) Pub. Date: Dec. 13, 2001

(54) Band-Switched Integrated Voltage Controlled Oscillator

(76) Inventors: Jean-Marc Mourant, Groton, MA (US); James Imbornone, Methuen, MA (US)

Correspondence Address: RATNER & PRESTIA, ONE WESTLAKES BERWYN, SUITE 301, P.O. BOX 980, VALLEY FORGE, PA, 19482, US

(21) Appl. No.: 09/483,368

(22) Filed: Jan. 14, 2000

(51) Int. Cl. H03B 5/12; H03J 5/24; H03J 7/08

(52) U.S. Cl. 331/117 R; 331/117 FE; 331/177 V; 331/179

(57) ABSTRACT

The source to drain capacitance of a FET device is used by connecting the source and drain together electrically so as to form a two terminal capacitive device which may be switched into and out of a parallel resonant circuit. Thus, sets of FET devices with their sources and drains connected together are employed in a circuit which produces and output voltage signal at a frequency which is tunable within a plurality of different individual bands. The resultant voltage controlled oscillator is particularly useful in cellular telephone and related wireless systems and/or in any other situation where integrated high frequency voltage control oscillator circuits are desired.

### BACKGROUND OF THE INVENTION

The present invention is generally directed to voltage controlled oscillator components and circuits. More particularly, the present invention is directed to a band-switched integrated voltage controlled oscillator employing field effect transistors as circuit elements whose capacitance varies as a function of applied voltage. Even more particularly, the present invention is directed to voltage controlled oscillator circuits which are particularly useful in frequency synthesizers and even more particularly useful in cellular telephone systems and devices.

Voltage controlled oscillators (VCO's) are commonly used in wireless electronic equipment, and elsewhere, as part of the frequency synthesizer systems. However, these circuits have so far resisted incorporation into integrated circuit devices. In virtually every cellular telephone, these circuits are built with discreet components. However, the discreet design poses many problems for designer of such systems.

In particular, the discreet components are physically large. Additionally, operation at high frequency is often very difficult or impossible due to the presence of parasitic effects produced by discreet sized components. Additionally, the cost for the discreet components, both in terms of their individual cost and the cost of assembly is high.

VCO circuits have been very hard to produce in integrated circuit form for several reasons. In particular, these circuits require variable reactors. In particular, capacitors have been seen to be considered as essential components of any VCO circuits. However, the standard integrated circuit manufacturing processes are not optimized or designed to produce such devices and in situations where they are produced, the quality of the on chip components is poor. In particular, integrated varactors have been seen to be both lossy and non linear.

It is noted that while the motivation for the present invention has arisen from wireless cellular telephone problems, it is nonetheless the case that applications for voltage controlled oscillators are essentially universal in nature. VCO's are considered to be basic system component building blocks. In particular, these circuits may be found in disk drives and/or in any other system in which it is desired to control oscillation frequency by means of an applied tuning voltage.

### SUMMARY OF THE INVENTION

In accordance with a preferred embodiment of the present invention a field effect transistor is employed as a variable capacitance device. In order to achieve this function from a field effect transistor, the source and drain of this device are electrically connected together to provide a first terminal of a two terminal capacitor. The Gate provides the other terminal.

In accordance with yet another embodiment of the present invention a voltage controlled tuning circuit comprises a resonant circuit which includes a capacitor together with a plurality of pairs of capacitive elements. Each of the capacitive elements is formed from a field effect transistor with its source and drain electrically connected together operating in effect as a variable capacitor in the manner described in the paragraph above. The plurality of pairs of capacitive elements are connected in parallel with the first capacitor. Means are provided for varying the effective capacitance of selected ones of the pairs of capacitive elements. In this way various ones of the capacitive element pairs may be switched into or out of a desired capacitive state. For example, by the inclusion of four such pairs, a four bit input provides a selection of up to 16 different bands.

Accordingly, it is an object of the present invention to provide an improved voltage controlled oscillator. It is also an object of the present invention to utilize the characteristics of FET devices in such a manner that they can be used as variable capacitors.

It is yet another object of the present invention to provide a voltage controlled oscillator circuit which may be integrated on a circuit chip in accordance with standard integrated circuit fabrication processes.

It is a still further object of the present invention to provide an integrated variable capacitor which is not lossy but which provides a linear response.

It is a still further object of the present invention to provide voltage controlled oscillator circuits which are particularly useful in wireless electronic equipment and even more particularly useful in cellular telephones and cellular telephone systems.

It is also an object of the present invention to provide a voltage controlled oscillator circuit which exhibits high frequency operational characteristics but which is relatively immune to parasitic effects.

It is a still further object of the present invention to provide a relatively low cost voltage controlled oscillator.

It is an even further object of the present invention to solve the problem associated with the poor quality of on-chip integrated circuit components which would otherwise be required.

It is a still further object of the present invention to provide a voltage controlled oscillator circuit which may be switched into and out of a plurality of different frequency bands.

Lastly, but not limited hereto, it is an object of the present invention to provide a high performance voltage controlled oscillator in an integrated circuit package.

The recitation herein of a list of desirable objects which are met by various embodiments of the present invention is not meant to imply or suggest that any or all of these objects are present as essential or necessary features, either individually or collectively, in the most general embodiment of the present invention or in any of its more specific embodiments.

### DESCRIPTION OF THE FIGURES

The subject matter which is regarded as the invention is particularly pointed out and distinctly claimed in the concluding portion of the specification. The invention, however, both as to organization and method of practice, together with further objects and advantages thereof, may best be understood by reference to the following description taken in connection with the accompanying drawings in which:

FIG. 1 is a schematic diagram illustrating the utilization of a field effect transistor device with the source and drain connected so as to be operable as a variable capacitance circuit element;

FIG. 2 is a schematic circuit diagram illustrating a voltage controlled oscillator in accordance with the present invention which utilizes the FET/ capacitive circuit illustrated in FIG. 1;

FIG. 3 is a schematic diagram of an alternate version of a voltage controlled oscillator in accordance with the present invention;

FIG. 4 is a plot of frequency versus tuning voltage; and

FIG. 5 is a simulated plot illustrating voltage controlled oscillator band switching such as occurs in the operation of the present invention.

### DETAILED DESCRIPTION OF THE INVENTION

The present invention takes advantage of the fact that when the source and drain of a field effect transistor, device such as a MOSFET, are connected together, the device is operable as a variable capacitor. In particular, the present invention takes advantage of the fact that the gate to source/drain capacitance varies significantly with the applied voltage. This circuit element provides several important benefits. In particular, the capacitive losses are much smaller when compared to the alternative P/N diode. Moreover, switching into capacitive mode induced by the applied voltage is abrupt. This makes the modified FET circuit element ideal for use in digital switching circuits. In particular, it is noted that such circuits are useful where-ever voltage controlled oscillators are employed, especially in high frequency operations such as cellular telephones and/or in certain computer disk drive circuits.

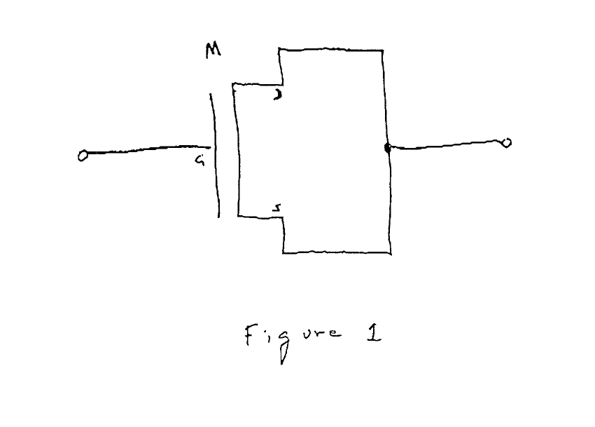

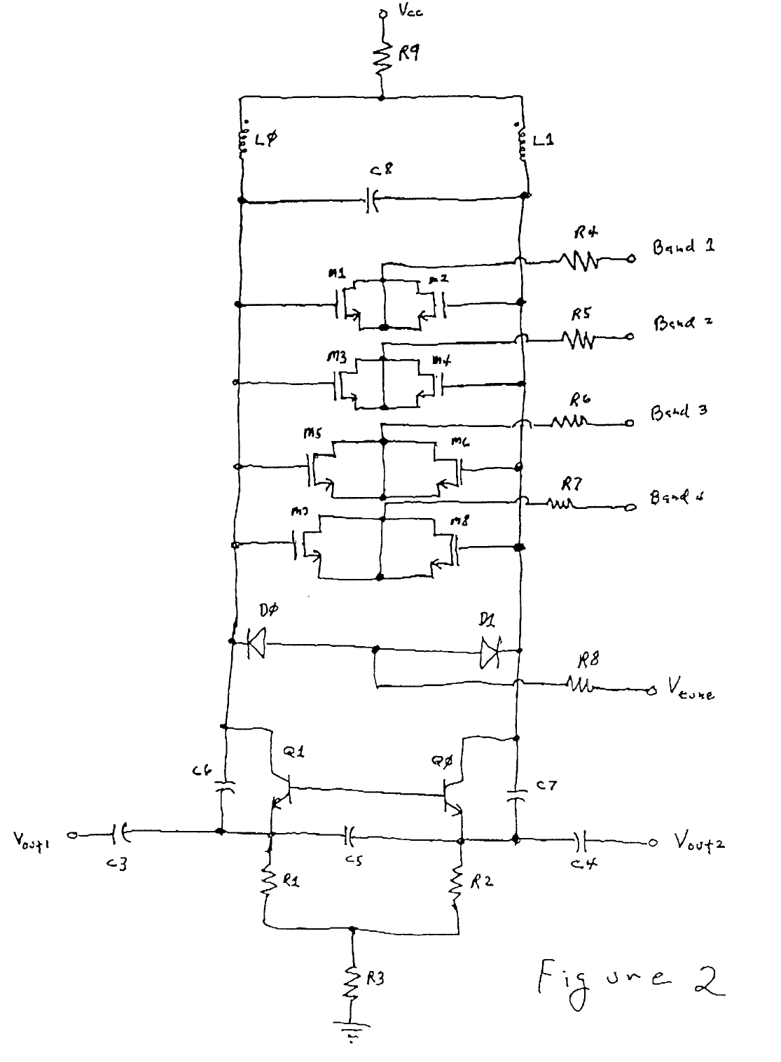

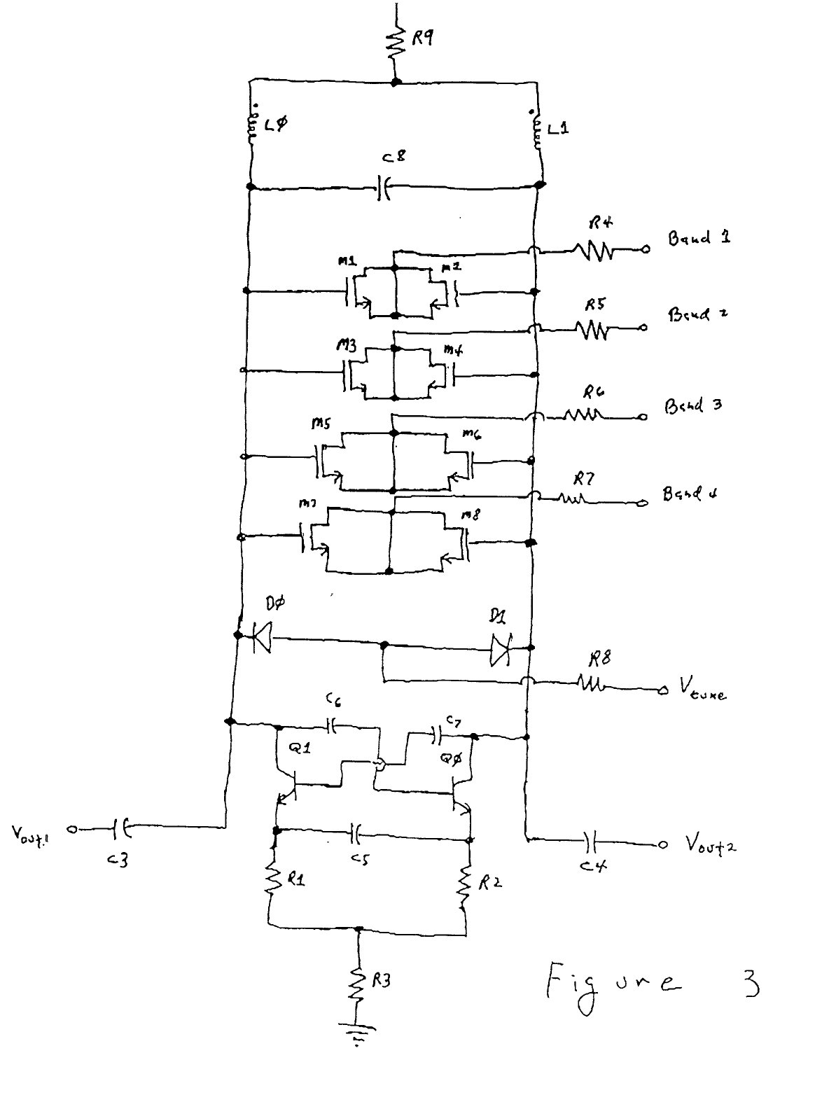

A voltage controlled oscillator in accordance with the present invention is illustrated in FIG. 2. A variation is also illustrated in FIG. 3. With respect to FIG. 2 it is noted that transistors Q₁ and Q₀ are connected in a standard oscillator circuit with the frequency of oscillation being determined by the resonant frequency of inductors L₀, L₁ and capacitor C₈, together with a variable capacitance provided by FET devices M₁ through M₈, as shown. More particularly, four pairs of variable capacitive elements are shown. For example M₁ and M₂ comprise one such pair as do M₃ and M₄, then M₅ and M₆ and finally M₇ and M₈. In each case the FET device has its source and drain connected as illustrated in FIG. 1. More particularly, through the application of band selection voltages through resistors R₄ through R₇ various levels of effective capacitance may be added to the resonant circuit which employs capacitor C₈ which thus acts as a defining lower capacitive limit for an LC resonant circuit which acts as the frequency control for the voltage controlled oscillator shown. By means of a tuning voltage applied through resistor R₈ to the junction of diodes D₀ and D₁ the capacitance of these devices is varied within the selected band.

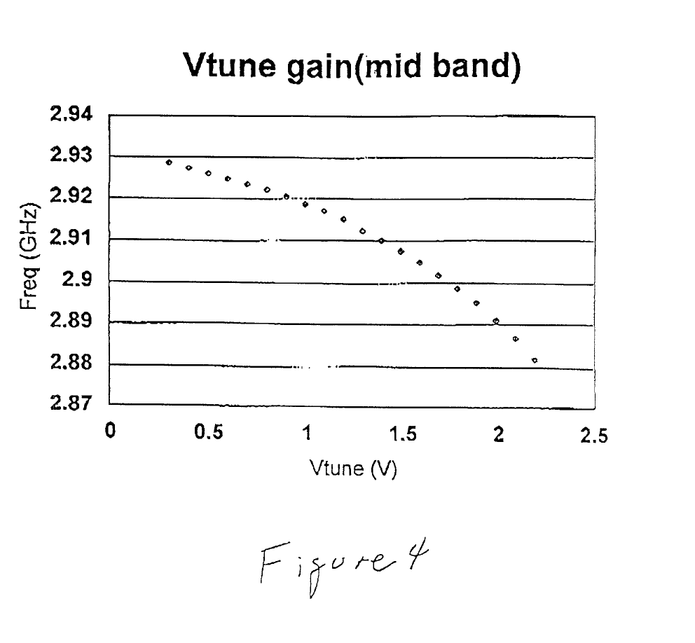

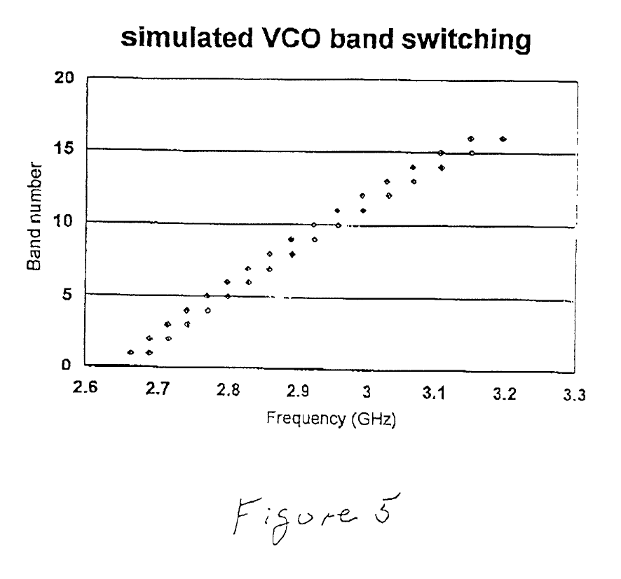

The variation of frequency as a function of tuning voltage within a mid-band frequency range is illustrated in FIG. 4. This Figure illustrates that it is possible to provide a frequency variation of approximately 50 megahertz over several frequency bands. Likewise in a sixteen band system, FIG. 5 illustrates the frequency overlap amongst the various bands.

In preferred embodiments of the present invention inductors L₀ and L₁ are one nanohenry devices; capacitors C₈ is a one picofarad capacitor; capacitors R₁, R₂, R₃, R₄, R₅, R₆, R₇ and R₈ are all one kilohm devices. Likewise capacitors C₃, C₅, C₄ and C₇ are one picofarad devices. This is also true of capacitors C₆ and C₇ in FIG. 4. R₉ is also a one kilohm resistor.

Accordingly, it should be appreciated that the circuit and FET utilization of the present invention meets all of the objects indicated above for the present invention. In particular it is noted that the present invention enables the switching of tens of bands with a single voltage control oscillator, with almost no penalty in circuit size. This is made possible by adding or subtracting capacitance in lump sum amounts thus changing the resonant frequency. By using lumps with binary weights, the band is selected directly with a single binary word without the necessity of a separate decoder circuit. In particular, it is seen that in the present invention the gate to source capacitance of an FET device is used directly and is a perfect match for the present application. More particularly the gate to source capacitance shows significant variation between the two states (when the FET is on and when it is off) and it is low loss device exhibiting high linearity in either of these states.

While the invention has been described in detail herein in accordance with certain preferred embodiments thereof, many modifications and changes therein may be effected by those skilled in the art. Accordingly, it is intended by the appended claims to cover all such modifications and changes as fall within the true spirit and scope of the invention.

The invention claimed is:

1. A two-terminal capacitor comprising;
a field effect transistor having a source, a Gate and a drain and electrical connections thereto wherein said source and drain are thereby electrically connected together to provide a first terminal of said capacitor, said Gate connection providing said second terminal.

2. The capacitor of claim 1 in which said transistor is a MOSFET.

3. A voltage controlled tuning circuit comprising:
a resonant circuit including a capacitor;
a plurality of pairs of capacitive elements with at least one of said capacitive elements comprising a FET device with its source and drain connected together to form one terminal of a two terminal capacitive element with the base of said FET device being the second terminal of said at least one capacitive element, with each of said members of said pairs being connected in series, and with said pairs of capacitive elements being connected in parallel with the capacitor in said resonant circuit; and
means for varying the capacitance of selected ones of said pairs of elements.

4. The circuit of claim 3 in which said varying means comprises circuits for applying voltage to select ones of said Gates.

5. The circuit of claim 3 in which each one of said pairs comprises FET devices.
